(19) United States
(12) Patent Application Publication
(10) Pub. No.: US 2017/0365547 A1
(43) Pub. Date: Dec. 21, 2017

(54) SEMICONDUCTOR DEVICE, MANUFACTURING METHOD, AND CONDUCTIVE POST

(71) Applicant: FUJI ELECTRIC CO., LTD., Kanagawa (JP)

(72) Inventors: Yoko NAKAMURA, Matsumoto-city (JP); Norihiro NASHIDA, Kita-Azumi-gun (JP)

(21) Appl. No.: 15/499,926

(22) Filed: Apr. 28, 2017

(30) Foreign Application Priority Data
Jun. 15, 2016 (JP) 2016-119291

(51) Int. Cl. H01L 23/498; H01L 27/12; H01L 29/66; H01L 29/78

(52) U.S. Cl. CPC H01L 23/49844; H01L 29/7827; H01L 27/1203; H01L 29/66666

(57) ABSTRACT

A semiconductor device comprises a semiconductor element 12 including electrodes 12G, 12S on a front surface and conductive posts 14, 14′, 14″ including one end which is soldered to electrodes 12G, 12S of the semiconductor element 12. The conductive posts 14, 14′, 14″ includes a solder absorbing portion 14b having a larger surface area per unit length than that of a bottom portion at a position apart from the one end by a length equal to a height of a bottom portion 14a in an extending direction. When the conductive post is joined by a solder, the solder melted and flowing across a surface of the conductive post is absorbed in a large surface of the solder absorbing portion, thereby preventing the solder from reaching a wiring substrate.

The contents of the following Japanese patent application are incorporated herein by reference: NO. 2016-119291 filed on Jun. 15, 2016.

### BACKGROUND

### 1. Technical Field

The present invention relates to a semiconductor device, a manufacturing method, and a conductive post.

### 2. Related Art

A power semiconductor device (also simply referred to as a semiconductor device) is manufactured, for example, by equipping a power semiconductor element (also simply referred to as a semiconductor element) and a wiring substrate on an insulating substrate, joining a conductive post connected to the wiring substrate with the semiconductor element and/or the insulating substrate to conduct electrodes of the semiconductor element (that is, a front surface electrode and a back surface electrode) to an external terminal, and further having them packaged (for example, refer to Patent Document 1). Here, the conductive post is joined with the semiconductor element and the like by soldering, that is, by applying a solder on the front surface electrode and the like of the semiconductor element, and having it in contact with an end portion of the conductive post to melt the solder.

Patent Document 2 discloses a lead pin configured by a plurality of strands coated with coating layer, respectively, and tightly twisted with one another. When this lead pin is used as a conductive post (that is, an external terminal) to connect to an electrode on the substrate on which the semiconductor device is implemented, its flexibility can absorb a heat deformation which occurs between the substrate and the lead pin resulting from a heat emitted by the semiconductor device. Also, it is quoted that a large area in contact with the solder increases a joint strength, thereby preventing disconnection due to cracking, breaking, peeling and the like of the solder. Patent Document 1: Japanese Patent Application Publication No. 2009-64852
Patent Document 2: Japanese Patent Application Publication No. H9-307053

An appropriate application amount of the solder forms a fillet at the end portion of the conductive post with a melted solder to provide a good joint. However, an excessive amount of the solder may allow the solder to reach the wiring substrate across a surface of the conductive post to short different wiring layers on the wiring substrate, form a bridge between the wiring substrate and the adjacent conductive post, or fail to form a good fillet. Such an issue may occur in general not only when the conductive post is used for the semiconductor device, but also when the conductive post is soldered to the electrode and the like.

### SUMMARY

In a first aspect of the present invention, provided is a semiconductor device comprising: a semiconductor element including a first electrode on a front surface; and a first conductive post including a first end which is soldered to the first electrode of the semiconductor element, wherein the first conductive post includes a solder absorbing portion at a position being apart from the first end by a first length in an extending direction and having a larger surface area per unit length than that of a portion within the first length from the first end.

In a second aspect of the present invention, provided is a manufacturing method of a semiconductor device, comprising: preparing a semiconductor element which includes a first electrode on a front surface; preparing a first conductive post including a solder absorbing portion which has a larger surface area per unit length than that of a portion within a first length from a first end at a position apart from the first end by the first length in an extending direction; and soldering the first end of the first conductive post to the first electrode of the semiconductor element.

In a third aspect of the present invention, provided is a conductive post including a first end which is soldered to a first electrode of a semiconductor element, the semiconductor element including the first electrode on a front surface, the conductive post comprising: a solder absorbing portion having a larger surface area per unit length than that of a portion within a first length from the first end at a position apart from the first end by the first length in an extending direction.

The summary clause does not necessarily describe all necessary features of the embodiments of the present invention. The present invention may also be a sub-combination of the features described above.

### BRIEF DESCRIPTION OF THE DRAWINGS

FIG. 1A illustrates a configuration of a semiconductor device in accordance with the present embodiment, in a side view along a reference line AA in FIG. 1B.

FIG. 1B illustrates the configuration of the semiconductor device in accordance with the present embodiment, in a top view along a reference line BB in FIG. 1A.

FIG. 2A illustrates a configuration of a conductive post.

FIG. 2B illustrates a configuration of a conductive post in accordance with a first modification example.

FIG. 2C illustrates a configuration of a conductive post in accordance with a second modification example.

FIG. 2D illustrates a configuration of a conductive post in accordance with a third modification example.

FIG. 3A illustrates a joint state between the conductive post and a semiconductor element, a wiring substrate, and an insulating substrate, in a side view.

FIG. 3B illustrates the joint state between the conductive post and the semiconductor element, in a top view along a reference line BB in FIG. 3A.

FIG. 3C illustrates a joint state between the conductive post and the semiconductor element when the conductive post in accordance with the third modification example is used, in a top view along the reference line BB in FIG. 3A.

FIG. 4A illustrates a configuration of a wiring layer and a through hole on the wiring substrate.

FIG. 4B illustrates another configuration of the wiring layer and the through hole on the wiring substrate.

FIG. 5A illustrates a configuration of a slit of the wiring layer on the wiring substrate.

FIG. 5B illustrates another configuration of the slit of the wiring layer on the wiring substrate.

FIG. 5C illustrates still another configuration of the slit of the wiring layer on the wiring substrate.

FIG. 6 illustrates a configuration of the wiring layer on the insulating substrate with which an external terminal is joined and a modification example of a joint between the external terminal and the wiring layer, in a top view along a reference line CC in FIG. 3A.

FIG. 7 illustrates a flow of a manufacturing method of the semiconductor device.

### DESCRIPTION OF EXEMPLARY EMBODIMENTS

Hereinafter, the present invention are described through embodiments of the invention. However, the embodiments described below are not to limit the claimed invention. Also, all of combinations of features described in the embodiments are not necessarily required for a means for solving problems of the invention.

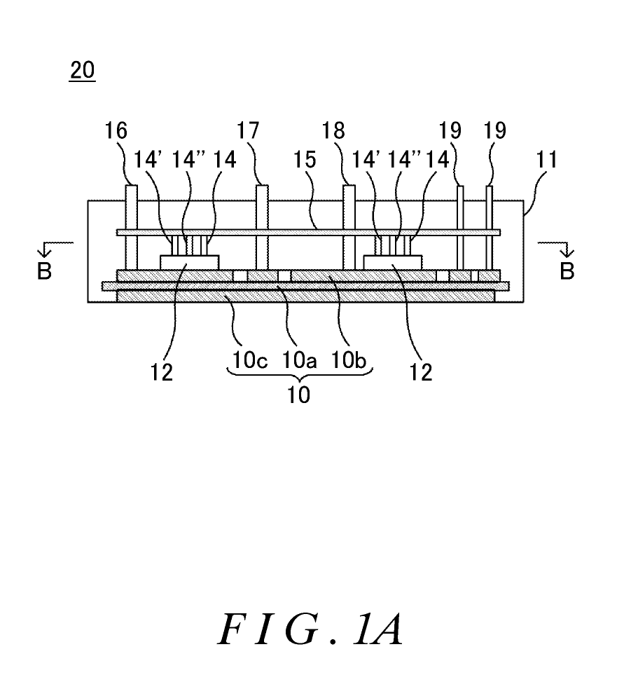

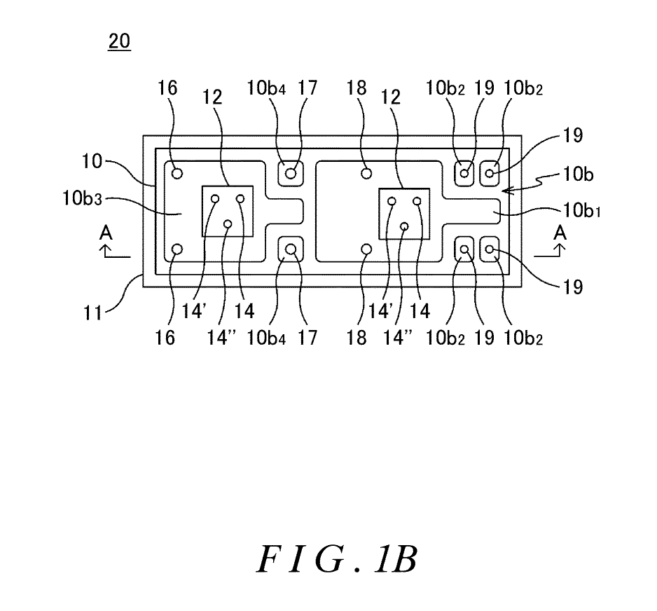

FIG. 1A and FIG. 1B illustrate a configuration of a semiconductor device 20 in accordance with the present embodiment. Here, FIG. 1A illustrates the configuration in a side view along a reference line AA in FIG. 1B, while FIG. 1B illustrates a configuration in a top view along a reference line BB in FIG. 1A. The semiconductor device 20 is designed to prevent different wiring layers on the wiring substrate from short, resulting from a solder used as a joint material for joint between the conductive post and the semiconductor element and the like flowing across a surface of the conductive post and reaching the wiring substrate to bridge the different wiring layers, to prevent a bridge from being formed between the wiring substrate and the adjacent conductive post, and to form a good fillet, thereby providing a good joint. The semiconductor device 20 includes an insulating substrate 10, a body 11, two semiconductor elements 12, first to third conductive posts 14, 14′, 14″, a wiring substrate 15 as one example of a substrate, external terminals 16 to 18, and an external terminal 19.

The insulating substrate 10 is a member equipped with two semiconductor elements 12, and may adopt, for example, a DCB (Direct Copper Bonding) substrate, an AMB (Active Metal Brazing) substrate and the like. The insulating substrate 10 includes an insulating board 10a, a joint layer (not shown), and metal layers 10b and 10c. The insulating board 10a is a plate-like member configured from, for example, insulative ceramics such as aluminum nitride, silicon nitride and aluminum oxide, and an insulative resin member such as epoxy resin. The joint layer is a layer formed of a joint material (for example, silver Brazing) which joins the metal layers 10b and 10c with the front surface and the back surface of the insulating board 10a, respectively. The metal layers 10b and 10c are layers formed of, for example, conductive metal such as copper and aluminum.

The metal layer 10b includes, as can be seen from FIG. 1B, a plurality of wiring patterns (here, eight wiring patterns, as one example) 10b₁, 10b₂, 10b₃ and 10b₄. The wiring pattern 10b₁ includes a rectangular portion for which the direction between the left and right sides of the figure is defined as a longitudinal direction, and an extended portion extending from the center of the right side of the rectangular portion to the right, and arranged in a region in the right half on the insulating substrate 10. The wiring pattern 10b₁ is equipped with one of the semiconductor elements 12. The wiring pattern 10b₂ has a rectangular shape. On the insulating substrate 10, two wiring patterns 10b₂ are arranged side by side on each of the upper side and the lower side of the extended portion of the wiring pattern 10b₁ as in the figure. The wiring pattern 10b₃ includes a rectangular portion and an extended portion extending from the center of the right side of the rectangular portion to the right, and arranged in a region in the left half on the insulating substrate 10. Wiring pattern 10b₃ is equipped with the other of the semiconductor elements 12. The wiring pattern 10b₄ has a rectangular shape. On the insulating substrate 10, one wiring pattern 10b₄ is arranged on each of the upper side and the lower side of the extended portion of the wiring pattern 10b₃ as in the figure.

The metal layer 10c is arranged across almost all regions of the back surface of the insulating substrate 10. The metal layer 10c is exposed from a bottom surface of the body 11 to function as a heat releasing board which releases a heat emitted by the semiconductor element 12 to the outside of the device.

The body 11 is a member to seal each constituent of the semiconductor device 20 therein while allowing upper ends of the external terminals 16 to 19 to protrude upward and exposing a lower surface of the insulating substrate 10 to be on the same plane as a bottom surface of the body 11. The body 11 is formed to have an approximately cuboid shape, for example, by mold forming using thermosetting resin such as epoxy resin.

Two semiconductor elements 12 are switching elements, for example, formed of a compound semiconductor such as SiC and may adopt a vertical metal oxide semiconductor field effect transistor (MOSFET), insulated gate bipolar transistor (IGBT) and the like which include electrodes on the front surface and the back surface, respectively. Note that the semiconductor element 12 may not only be a vertical element, but may also be a horizontal element provided with an electrode only on the front surface. Two semiconductor elements 12 are equipped on the wiring patterns 10b₁ and 10b₃ of the insulating substrate 10, respectively.

If the semiconductor element 12 is an MOSFET (or IGBT), it includes a source electrode (emitter electrode) and a gate electrode on the front surface, and a drain electrode (collector electrode) on the back surface. The semiconductor elements 12 are fixed on the insulating substrate 10 at the back surfaces thereof by connecting the drain electrodes (or collector electrodes) to the wiring patterns 10b₁ and 10b₃, respectively, with a joint material such as a solder.

The first to the third conductive posts (also referred to as an implant pin, a pin, a post and the like) 14, 14′, 14″ are conductive members provided between two semiconductor elements 12 and the wiring substrate 15 to permit conduction therebetween and are formed to have a columnar shape such as a cylinder by using conductive metal such as copper and aluminum, as one example. Note that the first to the third conductive posts 14, 14′, 14″ are arranged vertically on the semiconductor elements 12 by connecting the lower ends thereof to the semiconductor elements 12 with a joint material such as a solder, and have the upper ends thereof connected to the wiring layer on the wiring substrate 15 by soldering, brazing, or swaging.

The first to the third conductive posts 14, 14′, 14″ include a plurality of posts. Here, as one example, they include three posts to correspond to each of two semiconductor elements 12 (that is, six posts in total). Each two posts among them (that is, the first and the second conductive posts 14, 14′) are arranged vertically on the source electrodes of two semiconductor elements 12 or on the terminal connecting thereto, respectively, and connect to the wiring layer on the wiring substrate 15. Each one post (that is, the third conductive post 14″) is arranged vertically on the gate electrodes of two semiconductor elements 12 or on the terminal connecting thereto, respectively, and connects to the wiring layer on the wiring substrate 15.

Note that the configurations of the first to the third conductive posts 14, 14′, 14″ and details of joint with the semiconductor elements 12, the wiring substrate 15 and the insulating substrate 10 are described below.

The wiring substrate 15 is a substrate which connects the electrodes of two semiconductor elements 12 with one another and connects the electrode of the semiconductor element 12 with the external terminals 16 to 19. The wiring substrate 15 includes a wiring layer which forms a circuit pattern on an insulating board and its front surface. The insulating board may adopt, for example, a rigid substrate configured from glass epoxy material and the like or a flexible substrate configured from polyimide material and the like. The wiring substrate 15 is provided with a plurality of through holes through which the first to the third conductive posts 14, 14′, 14″ and the external terminals 16 to 19 extend. The wiring layer is provided on a front surface of the insulating board by using conductive metal such as copper and aluminum.

Note that details of the wiring layer on the wiring substrate 15 and the like are described below.

The external terminals 16 to 18 are terminals to conduct an electric current output from two semiconductor elements 12 and output it to the outside of the semiconductor device 20. The external terminals 16 to 18 are formed to have a columnar shape such as a cylinder by using conductive metal such as copper and aluminum, for example, similar to the first to the third conductive posts 14, 14′, 14″. Here, a concave portion is provided on the wiring patterns 10b₃, 10b₄ and 10b₁ of the insulating substrate 10 and lower ends of the external terminals 16 to 18 are engaged into the concave portion such that the external terminals 16 to 18 are arranged vertically on the wiring patterns 10b₃, 10b₄ and 10b₁ of the insulating substrate 10, respectively.

The external terminal 19 is a terminal to input a control signal from the outside of the semiconductor device 20 to two semiconductor elements 12. The external terminal 19 is formed to have a columnar shape such as a cylinder by using conductive metal such as copper and aluminum, for example, similar to the first to the third conductive posts 14, 14′, 14″. Here, a concave portion is provided on the wiring pattern 10b₂ of the insulating substrate 10 and a lower end of the external terminal 19 is engaged into the concave portion such that the external terminal 19 is arranged vertically on the wiring pattern 10b₂ of the insulating substrate 10 on a one-to-one basis.

Note that another example of the configurations of the external terminals 16 to 19 and joint with the insulating substrate 10 are described below.

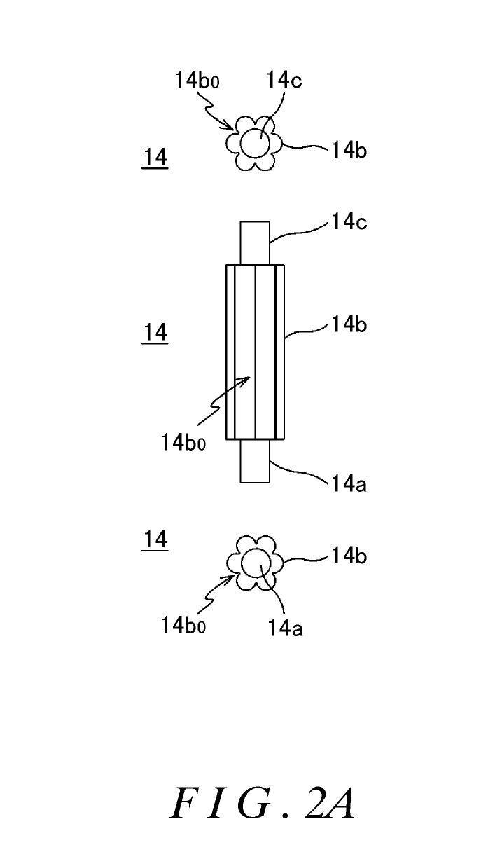

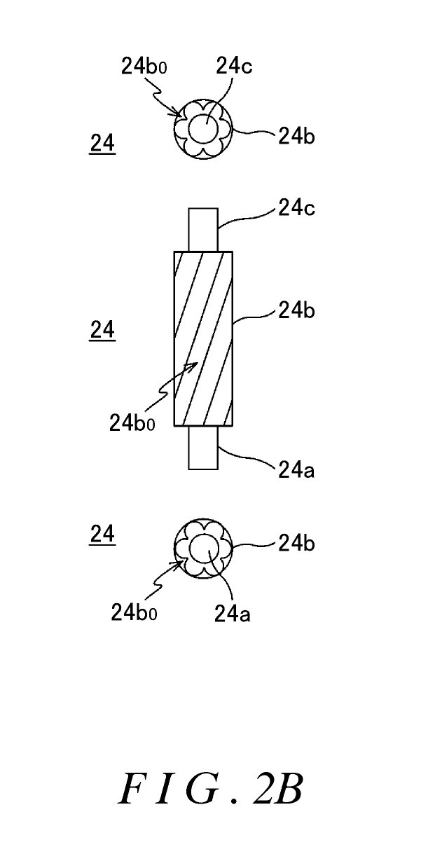

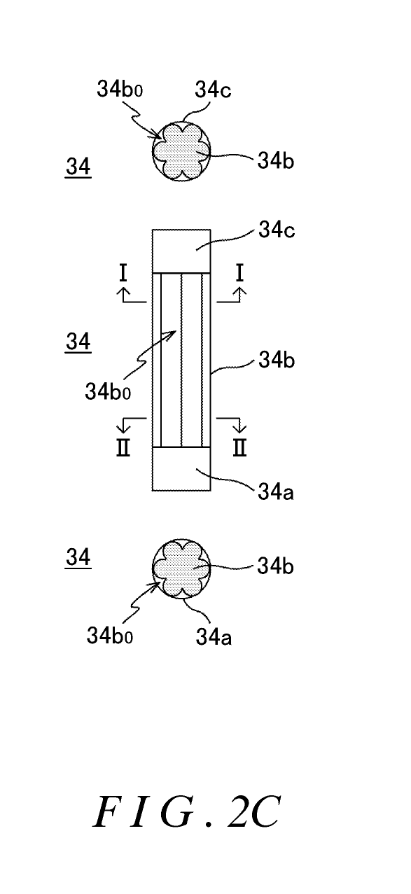

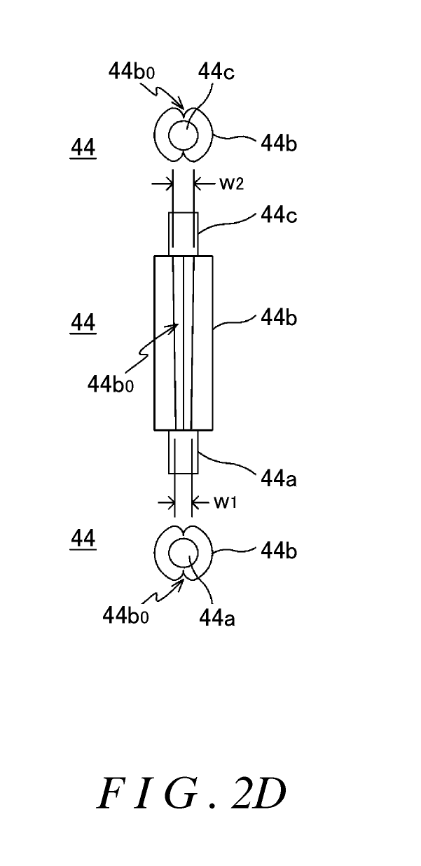

FIG. 2A illustrates a configuration of the first conductive post 14. However, the upper level, the middle level, and the lower level of the figure illustrate the configuration in a top view, in a front view, and in a bottom view, respectively. Note that as the second and the third conductive post 14′, 14″ are configured similar to the first conductive post 14, they are collectively referred to as the conductive post 14 unless otherwise specified in particular. The conductive post 14 is a columnar member which extends in a direction of one axis, and includes a bottom portion 14a, a solder absorbing portion 14b, and a head portion 14c.

The bottom portion 14a is formed to have a columnar shape such as a cylinder having a height equal to a first length and connects to the solder absorbing portion 14b at an upper end thereof to support the solder absorbing portion 14b. When the conductive post 14 is joined with the front surface electrode of the semiconductor element 12 by using a solder as described below, the bottom portion 14a allows a lower end thereof to contact the front surface electrode of the semiconductor element 12 via a solder layer and melt the solder to be buried in a fillet formed by the solder. Here, if a surface of the fillet has an ideal slope of approximately 45 degrees, for example, (that is, the height of the bottom portion 14a is almost equal to a half of a difference between the size of the front surface electrode and the diameter of the bottom portion 14a), the conductive post 14 is rigidly joined with the semiconductor element 12.

The solder absorbing portion 14b is a columnar trunk portion is supported on the bottom portion 14a, is much longer than heights of the bottom portion 14a and the head portion 14c described below (that is, the first length), and has a larger surface area per unit length in an extending direction than those of the bottom portion 14a and the head portion 14c. This allows a melted solder flowing across the surface of the conductive post when the conductive post 14 is soldered to be absorbed in the large surface of the solder absorbing portion 14b, thereby preventing the solder from reaching a wiring substrate to which the head portion 14c is connected.

The solder absorbing portion 14b can have the large surface area by, as one example, being formed to be thicker than the bottom portion 14a and the head portion 14c and further provided with a concavity on the surface. As one example of the concavity, a groove may be adopted. The conductive post 14 adopts one or more grooves 14b₀ (as one example, six grooves) parallel to the extending direction. This allows a large amount of the solder flowing across the surface of the conductive post 14 to be absorbed more efficiently.

The head portion 14c is formed to have a columnar shape such as a cylinder, and connects to an upper end of the solder absorbing portion 14b at a lower end thereof to be supported by the solder absorbing portion 14b. When the conductive post 14 is joined with the wiring substrate 15 as described below, the head portion 14c is engaged into a through hole of the wiring substrate 15.

The conductive post 14 may be manufactured similar to the solder absorbing portion 14b, but by compressing a member formed to extend in a direction of one axis at a constant interval by using a mold and the like to reduce a diameter and cutting the center of the compressed portion.

Note that the conductive post 14 may also be formed such that the head portion 14c and the bottom portion 14a have the same height, thereby having a symmetric shape even if the extending direction is reversed. This allows the conductive post 14 to be used even if the extending direction is reversed, that is, to be used with the bottom portion 14a as a head portion and the head portion 14c as a bottom portion.

FIG. 2B illustrates a configuration of a conductive post 24 in accordance with a first modification example. Note that the upper level, the middle level, and the lower level of the figure illustrate the configuration in a top view, in a front view, and in a bottom view, respectively. The conductive post 24 is a columnar member which extends in a direction of one axis similar to the conductive post 14 and includes a bottom portion 24a and a head portion 24c at its lower end and an upper end, respectively, and a solder absorbing portion 24b therebetween.

The bottom portion 24a and the head portion 24c are formed similar to those of the conductive post 14.

The solder absorbing portion 24b is provided with a concavity similar to that of the conductive post 14, but is provided with one or more grooves 24b₀ (as one example, six grooves) in a helical manner at an outer circumference as concavities. This allows the solder absorbing portion 24b to have a larger surface area and efficiently absorb a large amount of the solder flowing across a surface of the conductive post 24.

FIG. 2C illustrates a configuration of a conductive post 34 in accordance with a second modification example. Note that the upper level, the middle level, and the lower level of the figure are a cross-sectional view taken along a reference line I-I in the middle level, a front view, and a cross-sectional view taken along a reference line II-II in the middle level, respectively. The conductive post 34 is a columnar member which extends in a direction of one axis similar to the conductive post 14 and includes a bottom portion 34a and a head portion 34c at its lower end and an upper end, respectively, and a solder absorbing portion 34b therebetween.

The bottom portion 34a and the head portion 34c are formed similar to those of the conductive post 14, but to have a thickness equal to the largest diameter of the solder absorbing portion 34b.

The solder absorbing portion 34b is formed, similar to that of the conductive post 14, to be much longer than heights of the bottom portion 34a and the head portion 34c (that is, the first length) and to have a larger surface area per unit length in an extending direction than those of the bottom portion 34a and the head portion 34c. However, the solder absorbing portion 34b can have the large surface area by being formed to have a thickness equal to or less than those of the bottom portion 14a and the head portion 14c and further provided with a concavity on the surface. As one example of the concavity, similar to the conductive post 14, one or more grooves 34b₀ (as one example, six grooves) parallel to the extending direction may be adopted. Also, similar to the conductive post 24, one or more grooves (as one example, six grooves) provided in a helical manner at the outer circumference may also be adopted. This allows a large amount of the solder flowing across the surface of the conductive post 34 to be absorbed more efficiently.

FIG. 2D illustrates a configuration of a conductive post 44 in accordance with a third modification example. Note that the upper level, the middle level, and the lower level of the figure illustrate the configuration in a top view, in a front view, and in a bottom view, respectively. The conductive post 44 is a columnar member which extends in a direction of one axis similar to the conductive post 14 and includes a bottom portion 44a and a head portion 44c at its lower end and an upper end, respectively, and a solder absorbing portion 44b therebetween.

The bottom portion 44a and the head portion 44c are formed similar to those of the conductive post 14.

The solder absorbing portion 44b is provided with a concavity similar to that of the conductive post 14, but is provided with two grooves 44b₀ parallel to the extending direction at positions back to back as concavities. Two grooves 44b₀ are formed to be wider at an upper end than at a lower end. That is, a width w₂ at the upper end is larger than a width w₁ at the lower end. However, the number of the grooves 44b₀ are not limited to two, but may also be one or equal to or greater than three, and may also be provided to be not only parallel to the extending direction but also in a helical manner. This allows the solder absorbing portion 44b to have a larger surface area and efficiently absorb a large amount of the solder flowing across a surface of the conductive post 44.

Note that the groove 44b₀ is not only formed to be the widest at the upper end, but may also be formed to be wide at at least one position apart from the lower end.

Note that in the conductive posts 14 to 44, the solder absorbing portions 14b to 44b may also be provided with a stopper (not shown). The stopper may be provided by forming portions of the solder absorbing portions 14b to 44b to have large diameters, for example, by providing flanges. The stopper may stop the melted solder flowing across the surface of the conductive post. Also, the front surfaces of the solder absorbing portions 14b to 44b may also be processed to have rough surfaces such that they have larger surface areas.

Note that the external terminals 16 to 19 may also be configured similar to the conductive posts 14 to 44.

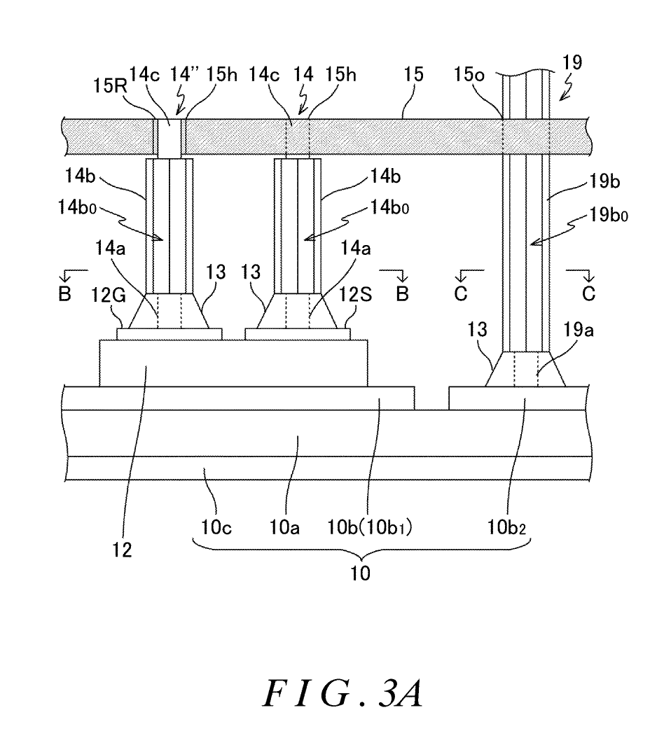

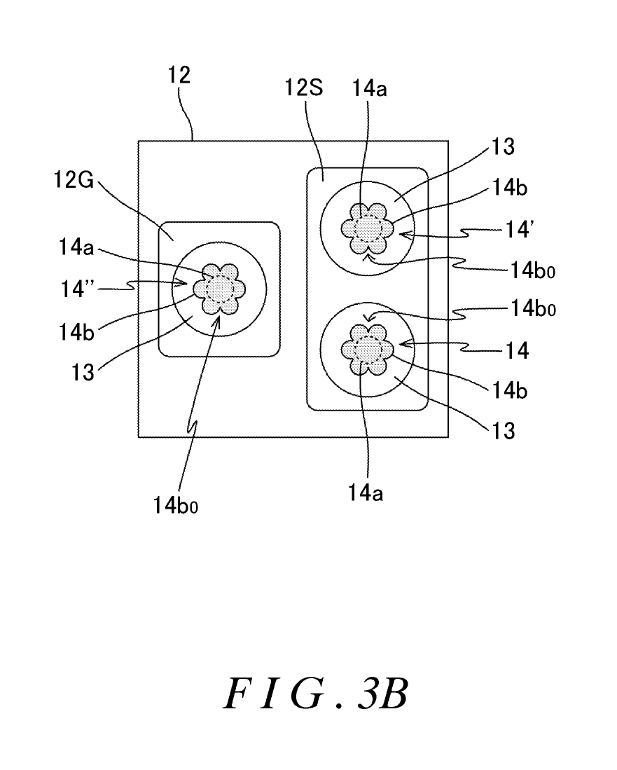

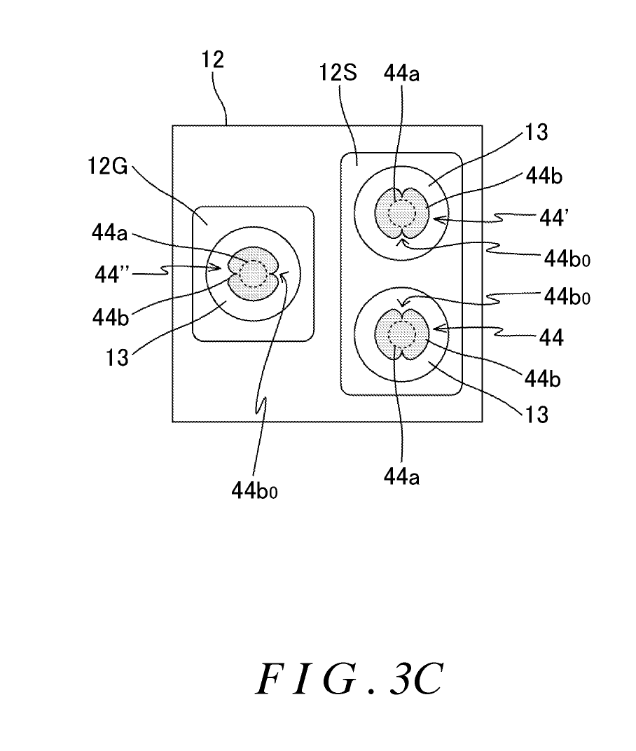

FIG. 3A and FIG. 3B illustrate a joint state between the first to the third conductive posts 14, 14′, 14″, and the semiconductor element 12, the wiring substrate 15, and the insulating substrate 10, in a side view, and a joint state between the first to the third conductive posts 14, 14′, 14″ and the semiconductor element 12, in a top view along a reference line BB in FIG. 3A, respectively. The wiring substrate 15 is provided to be opposing to a surface on which the front surface electrode of the semiconductor element 12 is provided, and the first to the third conductive posts 14, 14′, 14″ are connected between the front surface electrode of the semiconductor element 12 and the wiring substrate 15. Here, the semiconductor element 12 includes a gate electrode 12G which is one example of a second electrode at the left side of the figure, and a source electrode (or an emitter electrode) 12S as one example of a first electrode at the right side of the figure. Also, the wiring substrate 15 includes a control wiring layer and a main wiring layer (not shown in FIG. 3A and FIG. 3B) as described below.

Among the first to the third conductive posts 14, 14′, 14″, the third conductive post 14″ is joined on the gate electrode 12G and the first and the second conductive posts 14, 14′ are joined on the source electrode 12S to be adjacent to each other in a direction between the upper and lower sides of the figure, by using a solder, respectively. When the first to the third conductive posts 14, 14′, 14″ are soldered, a melted solder flows up across a surface of the bottom portion 14a and includes the bottom portion 14a inside, thereby forming a solder fillet 13 up to a lower end of the solder absorbing portion 14b.

The first to the third conductive posts 14, 14′, 14″ are connected to the wiring substrate 15 via the head portions 14c thereof. Here, a second through hole 15h is provided with a thin tubular plating layer 15R into which the head portion 14c is engaged, thereby connecting the first to the third conductive posts 14, 14′, 14″ to the wiring substrate 15 without a joint material used. This allows the third conductive post 14″ to connect the gate electrode 12G of the semiconductor element 12 to the control wiring layer of the wiring substrate 15 and the first and the second conductive posts 14, 14′ to connect the source electrode 12S to the main wiring layer. Here, the solder absorbing portion 14b is provided within a range from a position apart from the lower ends of the first to the third conductive posts 14, 14′, 14″ by the first length in the direction between the upper and lower sides of the figure, that is, from the upper end of the bottom portion 14a, to a position which does not contact the wiring substrate 15, thereby providing a gap between the solder absorbing portion 14b and the wiring substrate 15.

FIG. 3C illustrates a joint state between the first to the third conductive posts 14, 14′, 14″ and the semiconductor element 12 when the conductive post in accordance with the third modification example is used, in a top view along the reference line BB in FIG. 3A. The first to the third conductive posts 44, 44′, 44″ (all of which are configured similar to the conductive post 44 described above) are connected between the front surface electrode of the semiconductor element 12 and the wiring substrate 15.

Among the first to the third conductive posts 44, 44′, 44″, the third conductive post 44″ is joined on the gate electrode 12G and the first and the second conductive posts 44, 44′ are joined on the source electrode 12S to be adjacent to each other in a direction between the upper and lower sides of the figure, by using a solder, respectively. Here, the third conductive post 44″ on the gate electrode 12G includes grooves 44b₀ one of which is oriented to the right side of the figure, that is, toward the first and the second conductive posts 44, 44′ on the source electrode 12S. This allows a melted solder to be sucked up to the conductive post 44 across the groove 44b₀ oriented to the right side of the figure when soldering the first to the third conductive posts 44, 44′, 44″, thereby preventing the solder from bridging from the gate electrode 12G to the source electrode 12S. Also, the first and the second conductive posts 44, 44′ on the source electrode 12S allow one of the grooves 44b₀ thereof to be opposing to each other, respectively. This allows the melted solder to be sucked up to the conductive post across the opposing grooves 44b₀ when soldering the first and the second conductive posts 44, 44′, thereby preventing the solder from bridging between the first and the second conductive posts 44, 44′ on the source electrode 12S, and thereby forming fillets at the lower ends of the first and the second conductive posts 44, 44′, respectively.

Note that when a plurality of conductive posts are joined with the semiconductor element, the grooves may also be oriented to adjacent conductive posts, respectively. That is, if a plurality of conductive posts are adjacent to one another, the conductive post may also be provided with grooves oriented to adjacent conductive posts, respectively. Note that if a groove is not parallel to the extending direction of the conductive post, for example, when the groove is provided in a helical manner, the lower end of the groove may also be oriented to an adjacent conductive post. This allows a melted solder to be sucked up to the conductive post across the groove from the adjacent conductive post side when soldering the conductive post to the semiconductor element and the like, thereby preventing a bridge from being formed between the conductive posts.

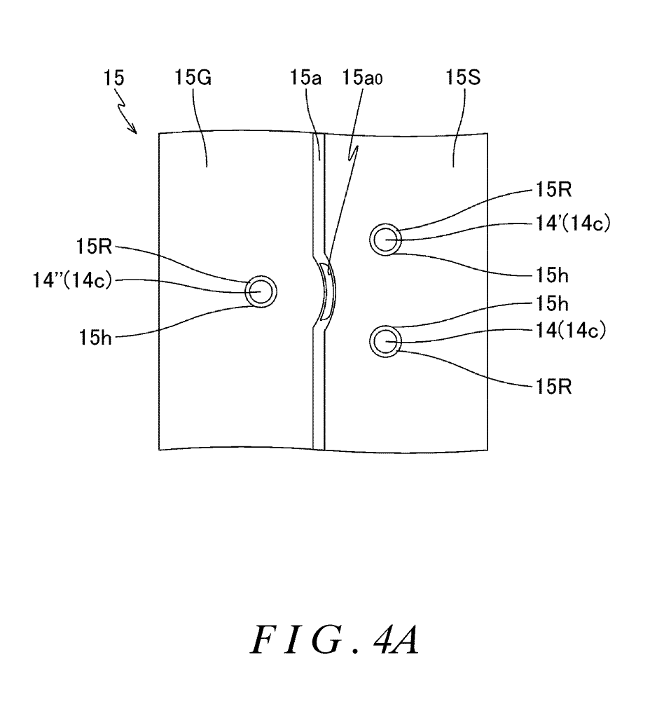

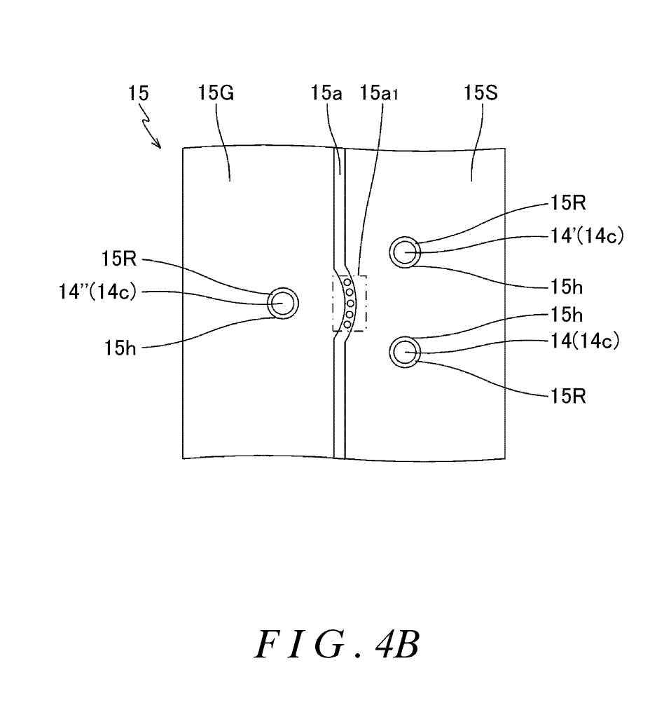

FIG. 4A illustrates a configuration of the wiring layer and the through hole on the wiring substrate 15. The wiring substrate 15 includes the wiring layer formed on the front surface of the insulating board, as described above. The wiring layer includes a control wiring layer 15G which is one example of a second wiring layer at the left side of the figure, and a main wiring layer 15S which is one example of a first wiring layer at the right side of the figure. The third conductive post 14″ joined with the gate electrode 12G of the semiconductor element 12 is connected to the control wiring layer 15Q and the first and the second conductive posts 14, 14′ joined with the source electrode 12S are connected to the main wiring layer 15S, respectively. Note that the control wiring layer 15G and the main wiring layer 15S are apart from each other in a direction between the left and right sides of the figure, with a gap (referred to as an insulating portion 15a) positioned therebetween which exposes a front surface of the insulating board. Here, the control wiring layer 15G includes a center of the right end in the figure which convexly protrudes toward the right side while the main wiring layer 15S includes a center of the left end in the figure which concavely notched toward the right side, which allows the gap to have a center thereof which is arc-like and curved toward the right side while maintaining a constant width.

In the insulating portion 15a, in particular, within a curved range positioned between a position at which the second through hole 15h is provided to which the third conductive post 14″ in the control wiring layer 15G is connected and a position at which two second through holes 15h are provided to which the first and the second conductive posts 14, 14″ in the main wiring layer 15S are connected, the first through hole 15a₀ penetrating the wiring substrate 15 is provided. Therefore, when soldering the first to the third conductive posts 14, 14′, 14″, even if a melted solder reaches the wiring substrate 15 across the surface of the conductive post, for example, even if the solder leaks from the second through hole 15h of the control wiring layer 15G and flows toward the main wiring layer 15S, and even if the solder leaks from the second through hole 15h of the main wiring layer 15S and flows toward the control wiring layer 15G, the solder is isolated by the first through hole 15a₀, thereby preventing the solder from bridging between the control wiring layer 15G and the main wiring layer 15S.

FIG. 4B illustrates another configuration of the wiring layer and the through hole on the wiring substrate 15. The insulating portion 15a may also be provided with not only one, but also a plurality of through holes which may have arbitrary shapes. For example, five first through holes 15a₁ may also be arranged side by side which include circular openings along the insulating portion 15a.

Note that the first through hole 15a₀ or 15a₁ is not only provided within a curved range of the insulating portion 15a, but may also be provided in wider range between the control wiring layer 15G and the main wiring layer 15S. Also, not only one first through hole 15a₀, but also a plurality of first through holes 15a₀ may also be arranged side by side in a width direction of the insulating portion 15a (that is, a direction between the left and right sides of the figure). Also, the wiring substrate 15 may also be configured by a plurality of substrates which are provided with the control wiring layers 15G and the main wiring layers 15S, respectively, and arranged to be apart from one another and opposing to the insulating substrate 10.

Note that providing the wiring substrate 15 with the first through hole 15a₀ or 15a₁ further allows resin to flow between the insulating substrate 10 and the wiring substrate 15 when mold forming the body 11. Also, an anchor effect makes the resin in closer contact with the wiring substrate 15, thereby making it hard for the resin to be peeled from the wiring substrate 15 even if the temperature of the body 11 rises due to a heat emitted by the semiconductor element 12.

Also, correspondingly to a position at the wiring layer on the wiring substrate 15 to which the conductive post is connected, a grooved portion, for example, a slit may also be provided at the position to allow the solder to flow therein.

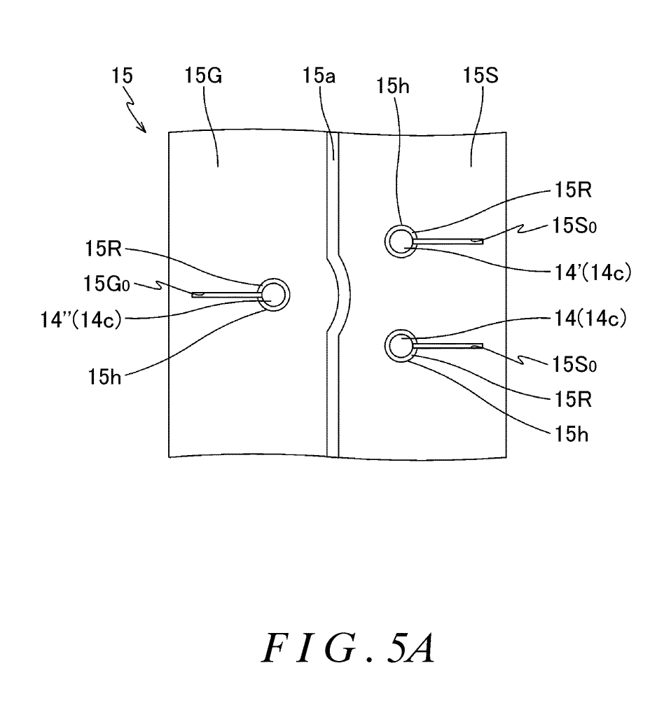

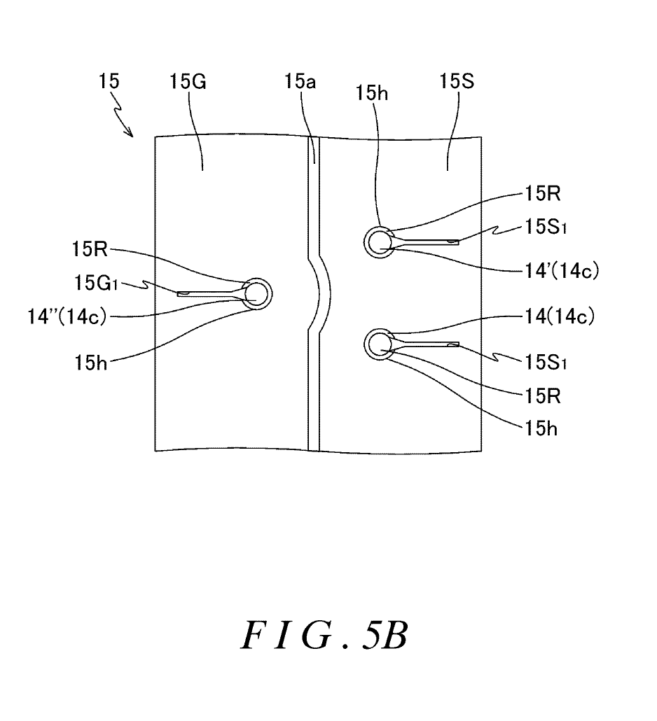

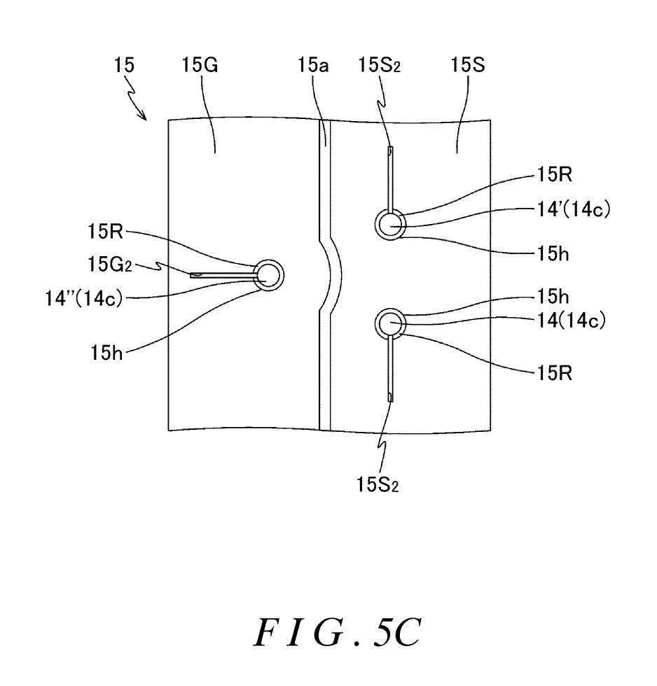

FIG. 5A illustrates a configuration of a slit of the wiring layer on the wiring substrate 15. The control wiring layer 15G (including the tubular plating layer 15R) on the wiring substrate 15 includes a slit 15G₀ formed therein which is one example of a grooved portion. The slit 15G₀ includes one end which contacts the second through hole 15h into which the head portion 14c of the third conductive post 14″ is engaged, and extends in a direction to be apart from a border between the control wiring layer 15G and the main wiring layer 15S (that is, the insulating portion 15a), that is, in the left direction in the figure. Also, the main wiring layer 15S (including the tubular plating layer 15R) includes a slit 15S₀ formed therein as one example of a grooved portion. The slit 15S₀ includes one end which contacts the second through hole 15h into which the head portions 14c of the first and the second conductive posts 14, 14′ are engaged, and extends in a direction to be apart from a border between the control wiring layer 15G and the main wiring layer 15S (that is, the insulating portion 15a), that is, in the right direction in the figure. Therefore, when the first to the third conductive posts 14, 14′, 14″ are soldered to the semiconductor element 12 and the like, even if a melted solder reaches the wiring substrate 15 across the surface of the conductive post, the slits can prevent a leaked solder from spreading and bridge between the control wiring layer 15G and the main wiring layer 15S. That is because, for example, the solder leaked from the second through hole 15h of the control wiring layer 15G flows into the slit 15G₀ and the solder leaked from the second through hole 15h of the main wiring layer 15S flows into the slit 15S0.

FIG. 5B illustrates another configuration of the slit of the wiring layer on the wiring substrate 15. On the wiring substrate 15, the control wiring layer 15G includes the slit 15G₁ formed therein which is one example of a grooved portion, and the main wiring layer 15S includes the slit 15S₁ formed therein which is one example of a grooved portion. The slits 15G₁ and 15S₁ are formed similar to the slits 15G₀ and 15S₀ described above, however, the slits 15G₁ and 15S₁ are formed to include wide ends which connect to the second through hole 15h. This facilitates the solder leaked from the second through hole 15h to be guided to the slits 15G₁ and 15S₁.

FIG. 5C illustrates still another configuration of the slit of the wiring layer on the wiring substrate 15. On the wiring substrate 15, the control wiring layer 15G includes the slit 15G₂ formed therein which is one example of a grooved portion, and the main wiring layer 15S includes the slit 15S₂ formed therein which is one example of a grooved portion. The slit 15G₂ is formed similar to the slit 15G₀ described above. The slit 15S₂ is formed similar to the slit 15S₀ described above. However, the slit 15S₂ at the upper side of the figure extends to the upper side of the figure while the slit 15S₂ at the lower side of the figure extends to the lower side of the figure. This allows the solder leaked from two second through holes 15h of the main wiring layer 15S, respectively, to flow into the slit 15S₂ and thus flow in a direction apart from the other second through hole 15h, thereby preventing bridging between the first and the second conductive posts 14, 14′ of which the head portions 14c are engaged into two second through holes 15h, respectively.

Note that if a plurality of second through holes 15h are provided in the wiring layer on the wiring substrate 15, the slit is to be provided to extend in a direction to be apart from the adjacent through hole. This can prevent bridging between the first and the second conductive posts 14, 14′ of which the head portions 14c are engaged into the adjacent second through holes 15h.

Note that not only the slit provided in the wiring layer on the wiring substrate 15, but a groove may also be provided on the wiring layer or a hole may also be provided to penetrate the wiring substrate 15.

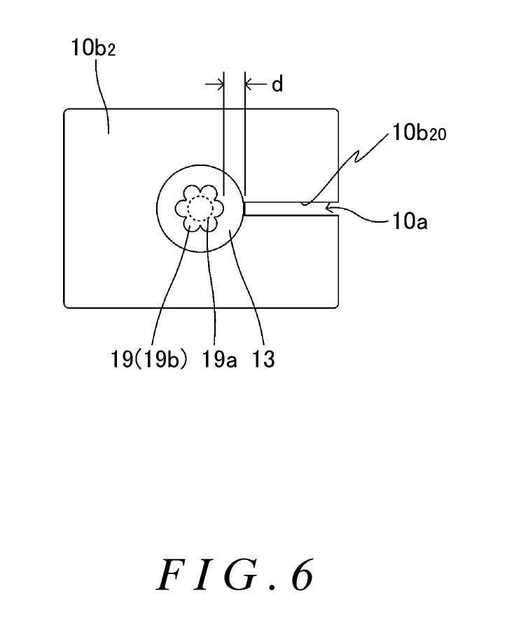

FIG. 6 illustrates a configuration of a wiring pattern on the insulating substrate 10 with which the external terminal 19 is joined and a modification example of a joint between the external terminal 19 and the wiring pattern, in a top view along a reference line CC in FIG. 3A. The external terminal 19 is arranged vertically on a wiring pattern 10b₂ of the insulating substrate 10 and penetrates through a third through hole 15o of the wiring substrate 15 to protrude from an upper surface of the body 11. The wiring pattern 10b₂ includes a slit 10b₂₀ formed therein to extend from the outer edge to the vicinity of a joint position with the external terminal 19, that is, extend to a position which is distance d apart from the surface of the solder absorbing portion 19b of the external terminal 19 in a top view.

When the external terminal 19 is soldered, a melted solder flows up across a front surface of the bottom portion 19a and includes the bottom portion 19a inside, thereby forming a solder fillet 13 up to a lower end of the solder absorbing portion 19b. Here, if a surface of the solder fillet 13 has an ideal slope of approximately 45 degrees (that is, the height of the bottom portion 19a is almost equal to a half of a difference between the wiring pattern 10b₂ and the diameter of the bottom portion 19a), the external terminal 19 is rigidly joined with the wiring pattern 10b₂ of the insulating substrate 10. In this case, the solder fillet 13 spreads its outer edge to a distal end of the slit 10b₂₀ or the close vicinity thereof. If an excessive amount of the solder is sucked into the surface of the external terminal 19, the excessive solder is flown into the slit 10b₂₀ to form the solder fillet 13 of an ideal size and the excessive solder is prevented from reaching the wiring substrate 15 across the surface of the external terminal 19.

Note that the external terminals 16 to 18 are also joined with the wiring patterns 10b₁, 10b₃ and 10b₄ of the insulating substrate 10, similar to the external terminal 19, and these wiring patterns 10b₁, 10b₃ and 10b₄ may also be configured similar to the wiring pattern 10b₂.

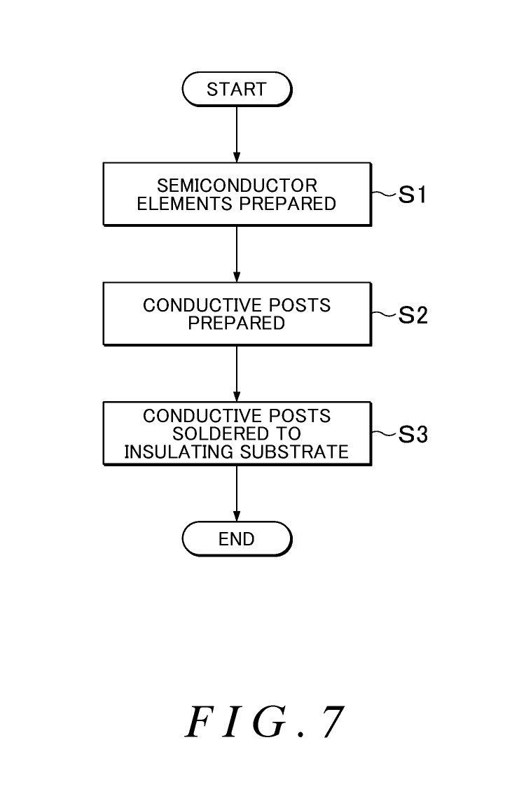

FIG. 7 illustrates a flow of a manufacturing method of a semiconductor device 20.

In step S1, the semiconductor elements 12 are prepared. One of two semiconductor elements 12 is equipped on the wiring pattern 10b₁ of the insulating substrate 10 via a solder layer, and the other is equipped on the wiring pattern 10b₃ via a solder layer.

In step S2, the first to the third conductive posts 14, 14′, 14″ and the external terminals 16 to 19 are prepared. The head portions 14c of first to the third conductive posts 14, 14′, 14″ are engaged into the second through holes 15h of the wiring substrate 15, and the external terminals 16 to 19 are inserted through the third through hole 150 of the wiring substrate 15 and fixed to the wiring substrate 15.

In step S3, the first to the third conductive posts 14, 14′, 14″ are soldered to the semiconductor element 12, and the external terminals 16 to 19 are soldered to the insulating substrate 10. First, the wiring substrate 15 is equipped on the insulating substrate 10. Here, a solder layer is provided on the front surface electrode of the semiconductor element 12, and the lower ends (of the bottom portions 14a) of the first to the third conductive posts 14, 14′, 14″ fixed to the wiring substrate 15 are made in contact with the solder layer. Similarly, a solder layer is provided on the wiring pattern of the insulating substrate 10, and the lower ends (of the bottom portions 19a) of the external terminals 16 to 19 fixed to the wiring substrate 15 are made in contact with the solder layer. Next, the solder is melted by using a reflow furnace and the like, the semiconductor element 12 and the external terminals 16 to 19 are joined on the insulating substrate 10, and the first to the third conductive posts 14, 14′, 14″ are joined on the front surface electrode of the semiconductor element 12. Finally, the insulating substrate 10, the semiconductor element 12, the wiring substrate 15, and other constituents are sealed within the body 11.

Note that in the present embodiment, the configuration of the conductive post and the like and the method of the joint thereof are described through an exemplary case in which the conductive post is arranged vertically on the front surface electrode of the semiconductor element or on the insulating substrate in the semiconductor device. However, not only they are applied to the conductive post joined with the semiconductor device, but in general, they may be widely applied to the conductive post joined with the electrode, the wiring pattern and the like.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

As is apparent from the description described above, according to (one) embodiment of the present invention, the semiconductor device, the manufacturing method, and the conductive post can be achieved.

What is claimed is:

1. A semiconductor device comprising:
a semiconductor element including a first electrode on a front surface; and
a first conductive post including a first end which is soldered to the first electrode of the semiconductor element, wherein
the first conductive post includes a solder absorbing portion at a position being apart from the first end by a first length in an extending direction and having a larger surface area per unit length than that of a portion within the first length from the first end.

2. The semiconductor device according to claim 1, wherein the solder absorbing portion includes a concavity provided on a surface of the first conductive post.

3. The semiconductor device according to claim 2, wherein the concavity is a groove.

4. The semiconductor device according to claim 3, wherein the concavity has a grooved shape parallel to an extending direction of the first conductive post.

5. The semiconductor device according to claim 3, wherein the concavity has a grooved shape provided in a helical manner at an outer circumference of the first conductive post.

6. The semiconductor device according to claim 3, wherein the groove has a position having a larger groove width at at least one position apart from an end portion of the first end side than that of an end portion of the first end side.

7. The semiconductor device according to claim 3, comprising a second conductive post being adjacent to the first conductive post and soldered to the first electrode, wherein the first conductive post has an end portion at the first end side in the concavity at the second conductive post side.

8. The semiconductor device according to claim 1, wherein the solder absorbing portion is thicker than the portion within the first length from the first end in an extending direction of the first conductive post.

9. The semiconductor device according to claim 1, wherein the solder absorbing portion has a thickness equal to or less than that of the portion within the first length from the first end in an extending direction of the first conductive post.

10. The semiconductor device according to claim 1, wherein the first conductive post has a symmetric shape even if the extending direction is reversed.

11. The semiconductor device according to claim 1, further comprising a substrate provided to be opposing to a surface on which the first electrode of the semiconductor element is provided and including a first wiring layer electrically connected to the first electrode by the first conductive post, wherein
the solder absorbing portion is provided within a range from a position which is apart from the first end by the first length in an extending direction of the first conductive post to a position which does not contact the substrate.

12. The semiconductor device according to claim 11, wherein
the semiconductor element further includes a second electrode on the front surface,
the semiconductor device further comprises a third conductive post including a first end which is soldered to the second electrode of the semiconductor element, and
the substrate further includes a second wiring layer electrically connected to the second electrode by the third conductive post.

13. The semiconductor device according to claim 12, wherein the substrate includes a first through hole provided in an insulating portion positioned between a position to which the first conductive post is connected in the first wiring layer and a position to which the third conductive post is connected in the second wiring layer.

14. The semiconductor device according to claim 13, wherein the substrate includes a plurality of the first through holes along the insulating portion.

15. The semiconductor device according to claim 12, wherein the first wiring layer includes a grooved portion which corresponds to a position to which the first conductive post is connected to allow a solder at the position to flow therein.

16. The semiconductor device according to claim 15, wherein the substrate includes a second through hole in which the first conductive post penetrates, and
the grooved portion includes one end which contacts the second through hole.

17. The semiconductor device according to claim 16, wherein the grooved portion extends from the one end which contacts the second through hole in a direction apart from a border between the first wiring layer and the second wiring layer.

18. The semiconductor device according to claim 1 further comprising a solder fillet formed to extend to a position within the first length from the first end of the first conductive post on the first electrode.

19. A manufacturing method of a semiconductor device, comprising:
preparing a semiconductor element which includes a first electrode on a front surface;
preparing a first conductive post including a solder absorbing portion which has a larger surface area per unit length than that of a portion within a first length from a first end at a position apart from the first end by the first length in an extending direction; and
soldering the first end of the first conductive post to the first electrode of the semiconductor element.

20. A conductive post including a first end which is soldered to a first electrode of a semiconductor element, the semiconductor element including the first electrode on a front surface, the conductive post comprising:
a solder absorbing portion having a larger surface area per unit length than that of a portion within a first length from the first end at a position apart from the first end by the first length in an extending direction.
